(19) United States
(12) Patent Application Publication
(10) Pub. No.: US 2017/0241019 A1
(43) Pub. Date: Aug. 24, 2017

(54) PE-ALD METHODS WITH REDUCED QUARTZ-BASED CONTAMINATION

(71) Applicant: Ultratech, Inc., San Jose, CA (US)

(72) Inventors: Mark J. Sowa, Medford, MA (US); Adam Bertuch, Boston, MA (US); Ritwik Bhatia, Newton, MA (US)

(73) Assignee: Ultratech, Inc., San Jose, CA (US)

(21) Appl. No.: 15/417,896

(22) Filed: Jan. 27, 2017

Related U.S. Application Data
(60) Provisional application No. 62/298,402, filed on Feb. 22, 2016.

(51) Int. Cl. C23C 16/455; H01J 37/32; C23C 16/505

(52) U.S. Cl. CPC C23C 16/45536; C23C 16/45553; C23C 16/505; H01J 37/321; H01J 37/32183; H01J 2237/3321; H01L 21/0228

(57) ABSTRACT

Methods of performing PE-ALD on a substrate with reduced quartz-based contamination are disclosed. The methods include inductively forming in a quartz plasma tube a hydrogen-based plasma from a feed gas that consists essentially of either hydrogen and nitrogen or hydrogen, argon and nitrogen. The nitrogen constitutes 2 vol % or less of the feed gas. The hydrogen-based plasma includes one or more reactive species. The one or more reactive species in the hydrogen-based plasma are directed to the substrate to cause the one or more reactive species to react with a initial film on the substrate. The trace amounts of nitrogen serve to reduce the amount of quartz-based contamination in the initial film as compared to using no nitrogen in the feed gas.

### CROSS-REFERENCE TO RELATED APPLICATIONS

This Application claims the benefit of priority under 35 USC 119(e) of U.S. Provisional Patent Application Ser. No. 62/298,402, filed on Feb. 22, 2016, and which is incorporated herein by reference.

### FIELD

The present disclosure relates to atomic-layer deposition (ALD), and in particular relates to plasma-enhanced ALD (PE-ALD), and more particularly relates to methods of performing PE-ALD in a manner that has reduced quartz-based contamination due to the interaction of the plasma with the quartz plasma tube used in an inductively coupled plasma source.

### BACKGROUND

Atomic layer deposition (ALD) is a method of depositing a thin film on a substrate in a very controlled manner. The deposition process is controlled by using one or more chemicals (“precursors”) in vapor form and reacting them sequentially and in a self-limiting manner on the surface of the substrate. The sequential process is repeated to build up the thin film layer by layer, wherein the layers are atomic scale.

ALD is used to form a wide variety of films, such as binary, ternary and quaternary oxides for advanced gate and capacitor dielectrics, as well as metal-based compounds for interconnect barriers and capacitor electrodes. An overview of the ALD process is presented in the article by George, entitled “Atomic Layer Deposition: an Overview,” Chem. Rev. 2010, 110, pp 111-113 (published on the Web on Nov. 20, 2009). The ALD process is also described in U.S. Pat. No. 7,128,787. An example ALD system is disclosed in U.S. Patent Application Publication No. US2006/0021573.

One type of ALD is called Plasma-Enhanced ALD or “PE-ALD,” wherein a plasma is generated by a plasma source. The plasma includes radicals generated though the dissociation of a molecular feed gas. Thus, PE-ALD can also be referred to as Radical-Enhanced ALD or “RE-ALD.” The radicals are directed to a target substrate by a pressure differential in a reactor chamber. An example PE-ALD system is described in WO 2015/080979.

A variety of plasma sources can be used for PE-ALD. One example plasma source is an inductively coupled plasma (ICP) source. One type of ICP source utilizes a dielectric plasma tube through which the process (precursor) gases flow at reduced pressures (e.g., 1 mTorr to 10 Torr). The dielectric plasma tube is typically made of quartz (SiO₂). An inductive coil is wrapped around the dielectric plasma tube and radio frequency (RF) power is delivered to the coil from an RF power supply, thereby creating a high-density plasma from the low-pressure feed gas that flows through the dielectric plasma tube. Common plasma gases include: argon, nitrogen, oxygen, hydrogen, ammonia, etc.

When the plasma is formed from hydrogen or from a combination of hydrogen and argon, and when the dielectric plasma tube is quartz, the silicon (Si) and oxygen (O) atoms of the quartz (either individually, or as SiₓO_{y} clusters) can be transferred in various forms (e.g., various molecular compound as well as in atomic form) from the inside walls of the quartz plasma tube to the target substrate due to physical and chemical interactions between the plasma and the quartz. This quartz-based contamination can negatively impact the properties of the film formed on the substrate.

### SUMMARY

An aspect of the disclosure is a method of performing PE-ALD with reduced quartz-based contamination. The method includes: forming an initial film on a substrate using a precursor gas; purging the precursor gas; inductively forming in a quartz plasma tube a hydrogen-based (H-based) plasma from a feed gas that consists essentially of either hydrogen and nitrogen or hydrogen, argon and nitrogen, wherein the nitrogen constitutes 2 vol % or less of the feed gas, wherein the H-based plasma includes one or more reactive species; and directing the one or more reactive species to the substrate to cause the one or more reactive species to react with the initial film.

Another aspect of the disclosure is the method described above, wherein the substrate resides within an interior of a reactor chamber, the H-based plasma is formed in a plasma source pneumatically coupled to the interior of the reactor chamber, and wherein the act of directing the one or more reactive species to the substrate includes forming a pressure differential between the H-based plasma and the interior of reactor chamber.

Another aspect of the disclosure is the method described above, the method further includes forming the feed gas by combining the nitrogen and the hydrogen or the nitrogen, the hydrogen and the argon, wherein the nitrogen is added in the form of N₂ gas or NH₃ gas and wherein the hydrogen is added in the form of H₂ gas.

Another aspect of the disclosure is the method described above, wherein the nitrogen constitutes between 0.1 vol % and 2 vol % of the feed gas.

Another aspect of the disclosure is the method described above, wherein the nitrogen constitutes between 0.5 vol % and 1.5 vol % of the feed gas.

Another aspect of the disclosure is the method described above, wherein the nitrogen constitutes 1 vol % or less of the feed gas.

Another aspect of the disclosure is the method described above, wherein the precursor gas contains at least one of: niobium, tungsten, molybdenum, aluminum, gallium, indium, boron, copper, gadolinium, hafnium, silicon, tantalum, titanium, vanadium and zirconium.

Another aspect of the disclosure is the method described above, wherein the amount of the reduction of the quartz-based contamination is greater than 50× as compared to not using N in the feed gas.

Another aspect of the disclosure is the method described above, wherein the amount of the reduction of the quartz-based contamination is greater than 20× as compared to not using nitrogen in the feed gas.

Another aspect of the disclosure is the method described above, wherein the amount of the reduction of the quartz-based contamination is greater than 2× as compared to not using nitrogen in the feed gas.

Another aspect of the disclosure is a method of forming a hydrogen-based (H-based) plasma for use in a plasma reactor system that includes a quartz plasma tube. The method includes flowing a feed gas through the quartz plasma tube, wherein the feed gas consisting of either H and N or H, Ar and N; inductively forming from the feed gas flowing through the quartz plasma tube the H-based plasma; and wherein the amount of N in the feed gas constitutes between 0.1 vol % and 2 vol % of the feed gas.

Another aspect of the disclosure is the method described above, wherein the N in the feed gas constitutes between 0.5 vol % and 1.5 vol % of the feed gas.

Another aspect of the disclosure is the method described above, wherein the N in the feed gas constitutes between 0.1 vol % and 1 vol % of the feed gas.

Another aspect of the disclosure is the method described above, wherein the H-based plasma includes at least one reactive specie, and further includes using the at least one reactive specie in a plasma-enhanced atomic-layer deposition (PE-ALD) process to form a film on a substrate.

Another aspect of the disclosure is the method described above, wherein using the H-based plasma results in a reduction in an amount of quartz-based contamination of the film formed in the PE-ALD process that is greater than 50× as compared to not using N in the feed gas.

Another aspect of the disclosure is the method described above, wherein using the H-based plasma results in a reduction in an amount of quartz-based contamination of the film formed in the PE-ALD process that is greater than 20× as compared to not using N in the feed gas.

Another aspect of the disclosure is the method described above, wherein using the H-based plasma results in a reduction in an amount of quartz-based contamination of the film formed in the PE-ALD process that is greater than 2× as compared to not using N in the feed gas.

Another aspect of the disclosure is the method described above, wherein the PE-ALD process includes using a precursor gas having at least one of: niobium, tungsten, molybdenum, aluminum, gallium, indium, boron, copper, gadolinium, hafnium, silicon, tantalum, titanium, vanadium and zirconium.

Another aspect of the disclosure is the method described above, the method further includes forming the feed gas by combining N and H or N, H and Ar, wherein the N is added in the form of N₂ gas or NH₃ gas and wherein the H is added in the form of H₂ gas.

Another aspect of the disclosure is the method described above, wherein the at least one reactive specie is H*, and the method further includes causing the H* to react with an initial film to form the film on the substrate.

Another aspect of the disclosure is the method as described above, wherein the feed gas consists essentially of either H and N or H, N and Ar.

Another aspect of the disclosure is the method as described above, wherein the at least on reactive species includes H* and at least one of O*, C* and S*.

Additional features and advantages are set forth in the Detailed Description that follows, and in part will be readily apparent to those skilled in the art from the description or recognized by practicing the embodiments as described in the written description and claims hereof, as well as the appended drawings. It is to be understood that both the foregoing general description and the following Detailed Description are merely exemplary, and are intended to provide an overview or framework to understand the nature and character of the claims.

### BRIEF DESCRIPTION OF THE DRAWINGS

The accompanying drawings are included to provide a further understanding, and are incorporated in and constitute a part of this specification. The drawings illustrate one or more embodiment(s), and together with the Detailed Description explain principles and operation of the various embodiments. As such, the disclosure will become more fully understood from the following Detailed Description, taken in conjunction with the accompanying Figures, in which:

FIG. 1 is a schematic diagram of an example PE-ALD system used to carry out the PE-ALD methods disclosed herein that reduce quartz-based contamination of the film formed by the PE-ALD process; and

FIG. 2 is a close-up cross-sectional view of the plasma system of the PE-ALD system of FIG. 1, illustrating a small amount of nitrogen added to hydrogen-based plasma to reduce quart-based contamination of the film;

FIG. 3 is a plot of the growth-per-cycle (GPC) of SiₓO_{y} deposition as measured in Angstroms per cycle (Å/cycle) versus the hydrogen flow rate H-FR in standard cubic centimeters per minute (sccm) for the feed gas used to form the hydrogen-based plasma, wherein the plot shows an increase in the amount of quartz-based contamination on the substrate as the amount of H added to the plasma increases; and

FIG. 4 is a plot of the growth-per-cycle (GPC) of SiₓO_{y} deposition as measured in Angstroms per cycle (Å/cycle) for an hydrogen-based plasma versus the flow rate N₂-FR of N₂ gas (sccm), illustrating how trace amounts N₂ gas added to the feed gas that forms the hydrogen-based plasma reduces the amount of quartz-based contamination of the substrate.

### DETAILED DESCRIPTION

Reference is now made in detail to various embodiments of the disclosure, examples of which are illustrated in the accompanying drawings. Whenever possible, the same or like reference numbers and symbols are used throughout the drawings to refer to the same or like parts. The drawings are not necessarily to scale, and one skilled in the art will recognize where the drawings have been simplified to illustrate the key aspects of the disclosure.

The claims as set forth below are incorporated into and constitute part of this Detailed Description.

In the discussion below, the phrase “quartz-based contaminants” or “quartz-based contamination” and like terms mean contaminants or contamination that come from the quartz (SiO₂) of the quartz plasma tube as a result of the interaction of the hydrogen-based (H-based) plasma with the quartz plasma tube. The quartz-based contaminants can include quartz itself, as well as the atoms Si and O that make up quartz, and molecules based on the combination of these atoms, such as SiO, O₂, SiₓO_{y} clusters etc., formed from Si and O. The quartz-based contaminants can also include molecules that include H from the H-based plasma.

The “reduction” of quartz-based contamination (or quartz-based contaminants) as referred to herein is measured relative to the case where no nitrogen is used in the H-based plasma.

The percentage of N gas in feed gas is in terms of the number n_{N} of N atoms in the feed gas versus the total number of atoms n_{A} in the feed gas, i.e., [n_{N}/n_{A}]×100.In an example where the number of H atoms is n_{H} and the number of Ar atoms is n_{Ar}, the total number of atoms n_{A} is given by either n_{A} =n_{H} +n_{N} or n_{A} =n_{H} +n_{N} +n_{Ar}.

In the description below and in the claims, the term “consisting essentially of” as used with respect to the feed gas is meant to limit the feed gas to the stated gases as well as those that do not materially affect the basic and novel characteristics of feed gas with respect to the reduction in quartz-based contamination in the PE-ALD film-forming process. In an example, the feed gas can consist of either nitrogen and hydrogen or nitrogen, hydrogen and argon. In another example, the feed case can further include one or more gases that do not substantially impact the formation of the plasma formed from the feed gas, and that do not substantially affect the PE-ALD process and the quality of the film being formed, and in particular do not substantially affect the characteristic of the plasma that provides for reduced quartz-based contamination.

The term “plasma” as used herein includes reactive species or radicals such as H* and N* (and optionally Ar*), as well as other charged particles such as ions, electrons, etc. It is understood that reacting the plasma with the substrate surface or a film layer on the substrate surface generally means that the reactive species in the plasma is reacting with the substrate surface or the film layer. Thus, directing the plasma to the substrate is generally performed with the intent to cause the reactive species of the plasma to react with the substrate surface or the film layer even though other components of the plasma may reach the subsrate surface of the film layer and not cause a substantial reaction.

PE-ALD System

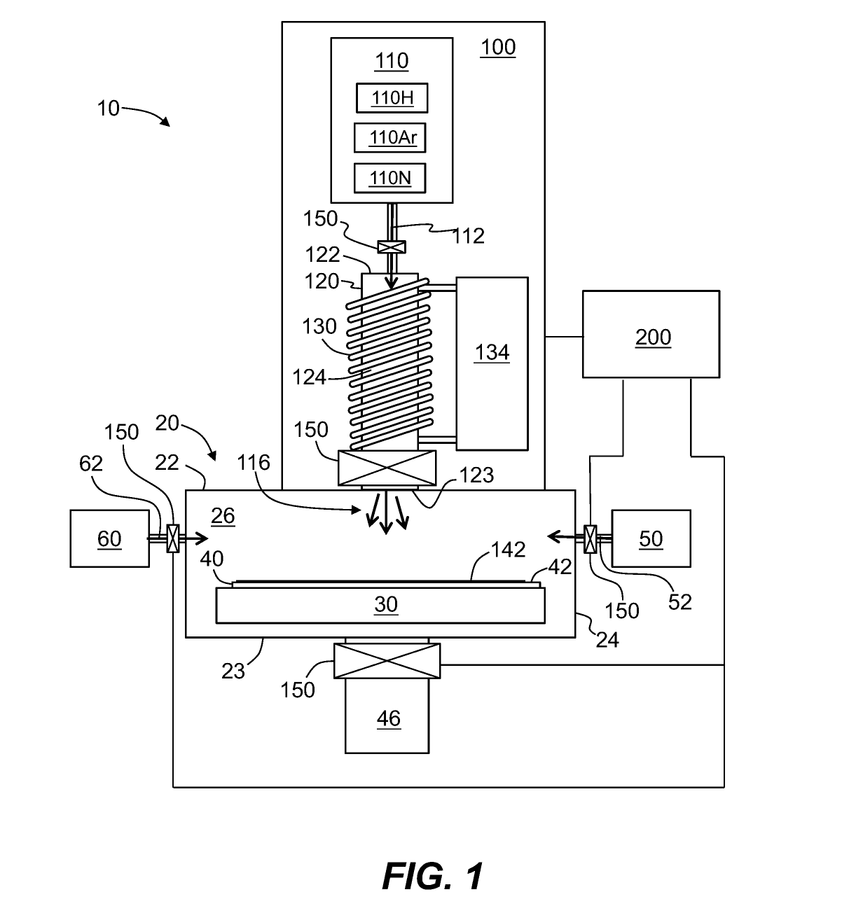

FIG. 1 is a schematic diagram of an example PE-ALD system 10. Various configurations for PE-ALD system 10 are possible, and the PE-ALD system 10 of FIG. 1 shows one basic configuration that can be employed. The PE-ALD system 10 includes a reactor chamber 20 having a top wall 22, a bottom wall 23 and a cylindrical sidewall 24 that define a reactor chamber interior 26. A stage 30 resides within the reactor chamber interior 26. The stage 30 supports a substrate 40 that has an upper surface 42 on which a film layer (“film”) 142 is formed via a PE-ALD process as discussed below. An example substrate 40 is a silicon wafer used in semiconductor manufacturing. A vacuum pump 46 is pneumatically connected to the reactor chamber interior 26 and serves to control the pressure within the reactor chamber interior 26 (e.g., in the range of about 10 mTorr to about 500 mTorr). The vacuum pump 46 is also used to define a pressure differential between the region of substrate 40 and the region near the top wall 22 of reactor chamber interior 26.

The PE-ALD system 10 also includes precursor gas source 50 that is pneumatically connected to the reactor chamber interior 26 and that provides a precursor gas 52 to the reactor chamber interior 26 as part of the PE-ALD process.

The PE-ALD system 10 further includes an optional second gas source 60 that is pneumatically connected to the reactor chamber interior 26 and that provides an inert gas 62 to the reactor chamber interior 26. The inert gas 62 serves as a purge gas between process steps and to speed up the sequential layering processes when forming film 142. Note that the second gas source 60 can be combined with the precursor gas source 50 so that the precursor gas 52 and the inert gas 62 can flow into the reactor chamber interior 26 through the same conduit.

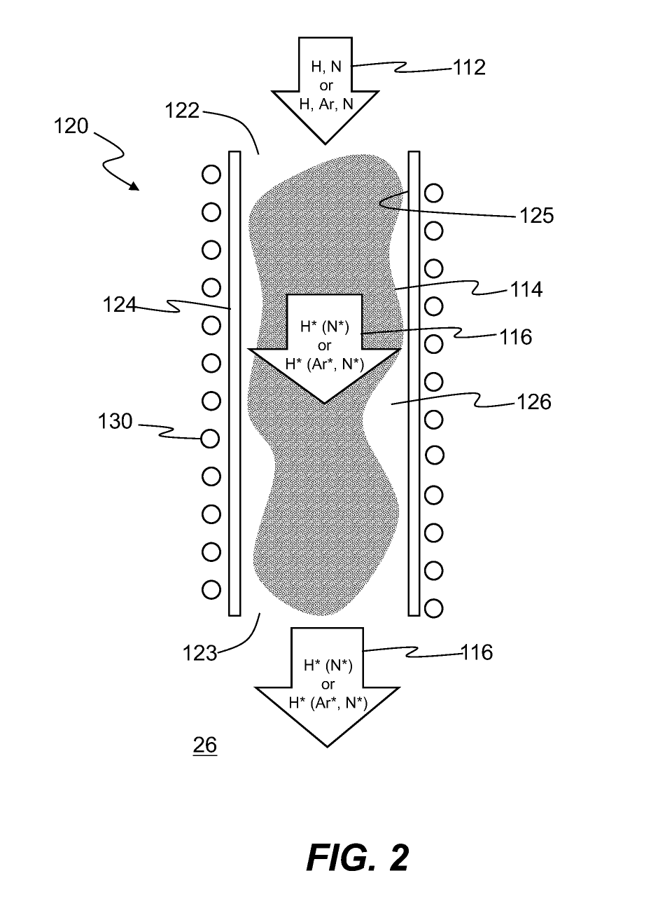

The PE-ALD system 10 also includes a plasma system 100 that is pneumatically coupled to the reactor chamber interior 26 at the top wall 22. FIG. 2 is a close-up cross-sectional view of a portion of an example plasma system 100. An example plasma system 100 includes a gas source system 110. The gas source system 110 contains a source 110H of hydrogen (H) gas, a source 110N of nitrogen (N) gas, and optionally includes a source 110Ar of argon (Ar) gas. The gas source system 110 emits a feed gas 112, which in examples can consist essentially of either H and N or H, Ar and N, as discussed below. In an example, the N gas from the gas source 110N is provided as N₂ and the H from the gas source 110H is provided as H₂. In another example, the N gas from the gas source 110N is provided as NH₃ gas.

The plasma system 100 includes a plasma tube 120 that has an input end 122, an output end 123, an outer surface 124, an inner surface 125 and an interior 126. The plasma tube 120 is made of quartz and is substantially cylindrical. The gas source system 110 is pneumatically coupled to the input end 122 of plasma tube 120. The plasma system 100 further includes a multi-turn coil 130 that resides around the outer surface 124 of plasma tube 120 and is operably connected to an RF source 134 and RF matching network. The plasma tube 120 and the multi-turn coil 130 define the gas source system 110 as an inductively coupled plasma source.

The PE-ALD system 10 can include a number of valves 150 that are used to control the flow of precursor gas 52, inert gas (purge gas) 62 and feed gas 112, as well as the pneumatic connection of vacuum pump 46, to the reactor chamber interior 26. The valve 150 at the output end 123 of gas source system 110 adjacent the reactor chamber 20 is optional and may not be required given the low pressure in the reactor chamber interior 26.

The PE-ALD system 10 also includes a controller 200 operably connected to the plasma system 100 and valves 150. The controller 200 is configured to control the operation of the PE-ALD system 10 to form a film 142 on the upper surface 42 of substrate 40. In particular, the controller 200 is configured to control the opening and closing of valves 150 as needed to perform the sequential introduction of precursor gas 52 and plasma 114 into the reactor chamber interior 26, including purge steps using inert gas 62 between the precursor and plasma steps. The process of forming film 142 includes forming an initial film and growing the film 142 via the sequential introduction of precursor gas 52 and plasma 114 (with purging between these two steps to remove reaction by-products, unreacted precursor gas 52, unreacted plasma, etc.) to form the final film of a desired thickness.

Method of Operation

With reference to FIG. 2, the feed gas 112 enters the input end 122 of plasma tube 120 as a feed gas and travels into the interior 126 of plasma tube 120. The RF source 134 provides the multi-turn coil 130 with an RF-frequency signal that inductively forms from the feed gas 112 an H-based plasma 114 within the interior 126 of plasma tube 120. More specifically, as the feed gas 112 flows towards the output end 123, the RF energy from the multi-turn coil 130 drives azimuthal electrical currents in the (rarified) feed gas 112, which initiates the formation of H-based plasma 114. The H-based plasma 114 includes one or more reactive species 116, e.g., H radicals (i.e., H* and N*) or H, Ar and N radicals (denoted H*, Ar* and N*) that enter the reactor chamber interior 26. Ar is typically used in combination with H in the feed gas 112 to enhance the formation of H* from H₂ gas. Thus, in an example, the main reactant (i.e., reactive specie) in an H-based plasma 114 is H*. The N* radical is not actually one of the reactive species 116 and so is shown in parenthesis “(N*)” in FIG. 2 because the radical N* does not actually react in any substantially way with the upper surface 42 of substrate 40 or film 142. This is also generally true of Ar*, which is a byproduct of the plasma-forming process, wherein the Ar in the feed gas 112 is used to enhance the formation of H*, which as noted above, is the primary if not the only reactive species 116 in the H-based plasma 114. In other examples, the feed gas 112 can include additional gases, such as O₂, CH₄ or H₂S, to create additional reactive species O*, C* and S*, respectively, in the H-based plasma 114.

Because the output end 123 of plasma tube 120 is pneumatically connected to the reactor chamber interior 26, and because the reactor chamber interior 26 has a relatively low pressure, the H-based plasma 114 and its attendant reactive species 116 and other charged components flow into the reactor chamber interior 26. At least one of reactive species 116 (e.g., just H*) causes a chemical reaction in the formation of a film 142 on the upper surface 42 of substrate 40. For example, reactive species 116 from a H-based plasma 114 can react with an initial film 142 formed using a Niobium-(Nb)-based precursor gas 52 (e.g., (t-butylimido) tris(diethylamido)niobium(V), (tBuN=)Nb(NEt₂)₃, TBTDEN) that forms an Nb-based film 142 having chemisorbed Nb precursor ligands. In this example, the at least one reactive specie 116 in the H-based plasma 114 is H*, which can react with the Nb precursor ligands to remove them from the initial film 142 to form a more pure Nb-based film 142. In other examples, the precursor gas 52 can comprise either tungsten (W) or molybdenum (Mo), which can be used to form WN or MoN, respectively, using the H-based plasma 114. In an example, the precursor gas 52 includes at least one of: niobium, tungsten, molybdenum, aluminum, gallium, indium, boron, copper, gadolinium, hafnium, silicon, tantalum, titanium, vanadium and zirconium.

When the feed gas 112 used to form the H-based plasma 114 consists essentially of pure H or consists essentially of H and Ar, the H-based plasma 114 can react with the inner surface 125 of plasma tube 120 and generate quartz-based contaminants. These quartz-based contaminants pass through the reactor chamber interior 26 and deposit onto the upper surface 42 of substrate 40 or deposit onto or otherwise become incorporated into the film 142 being formed on the upper surface 42 of substrate 40. This results in contamination of film 142.

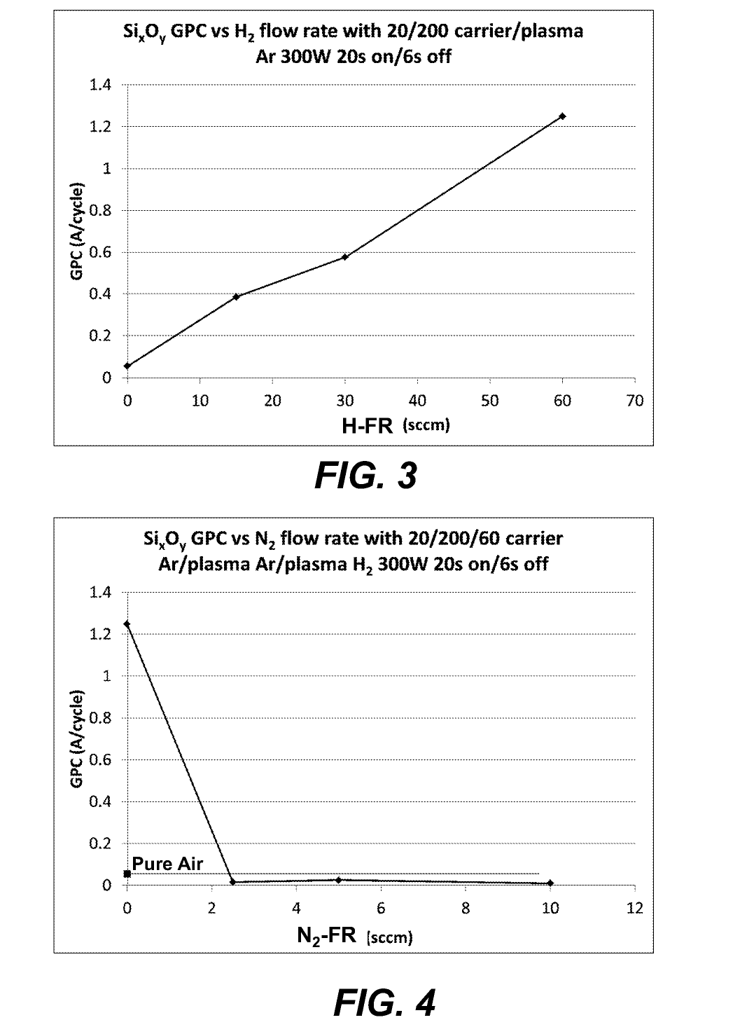

FIG. 3 is a plot of the growth-per-cycle (GPC) of SiO₂ deposition as measured in Angstroms per cycle (Å/cycle) versus the hydrogen flow rate H-FR in standard cubic centimeters per minute (sccm) for the feed gas 112 used to form the H-based plasma 114. The growth measurements were taken on a substrate placed in a PE-ALD system like the PE-ALD system 10 of FIG. 1. The substrate was exposed to a series of plasma cycles wherein the feed gas consisted of 200 sccm of argon and 0 to 60 sccm of hydrogen. The PE-ALD conditions were 300 W for 20 s, with 6 s between plasma exposures.

The pure argon plasma led to the deposition of 0.055Å of SiₓO_{y} material for each 20 s plasma exposure. Adding hydrogen to the argon plasma led to a linear increase in deposition rate from 0.385Å per cycle at 20 sccm hydrogen addition to 1.25Å per cycle at 60 sccm hydrogen addition. A 1.25Å deposition rate is, in many cases, greater than the expected PE-ALD growth rate of the film being formed, which indicates that these kinds of deposition conditions will lead to substantial film contamination.

It has been found that the addition of relatively small quantities of N gas to the hydrogen or hydrogen/argon feed gas 112 drastically reduces the rate of deposition of quartz-based contamination. As a consequence, the properties of the deposited film 142 are substantially improved and closer to ideal.

In various examples, the percentage of N gas in feed gas 112 is in the range from 0.1 vol % to 2 or 0.5 vol % to 1.5 vol %, or generally less than 1 vol %.

In experiments, the SiₓO_{y} deposition rates for the 200 sccm argon/60 sccm hydrogen plasma-forming conditions were studied at various low additions of nitrogen gas in the feed gas 112. FIG. 4 is a plot of the GPC (Å/cycle) versus the nitrogen flow rate N₂-FR (sccm) for 20/200/60 plasma-forming conditions. The addition of 2.5 sccm of nitrogen to the 200 sccm argon/60 sccm hydrogen reduced the SiₓO_{y} deposition rate from 1.25Å per cycle to 0.015Å cycle. A nitrogen gas addition of less than one percent of the total gas flow resulted in an 83 times reduction in silicon and oxygen transfer from the plasma tube 120 to the substrate 40.

The role of the N in the H-based plasma 114 in reducing quartz-based contamination is not fully understood. However, without being bound by theory, it is believed that the inner surface 125 of plasma tube 120 becomes passivated by nitrogen radicals N* in the H-based plasma 114 from the trace amounts of N in the feed gas 112, leaving the inner surface 125 to behave more like SiNₓ or SiON, which are less prone to removal from chemical or energetic interactions from the H-based plasma 114 than for SiO₂. The trace amounts of N* in the H-based plasma 114 generally do not substantially adversely affect the PE-ALD process, i.e., do not represent a substantial source of contamination for film 142.

In various examples, the amount of reduction in quartz-based contamination is greater than 70× or greater than 50×, or greater than 20× or greater than 10× or greater than 5×, or greater than 2×. In an example, the precise amount of nitrogen used in the feed gas 112 to form the H-based plasma 114 is based on a desired amount of reduction in the quartz-based contamination and optionally the sensitivity (if any) of the film 142 to the presence of trace amounts of N* in the H-based plasma 114. As noted above, in many if not most cases, the trace amounts of N* in the H-based plasmas 114 considered herein will have no substantial effect on the quality of film 142.

A variety of PE-ALD processes can benefit from the methods disclosed herein, including but not limited to forming films 142 of NbN, WN and MoN.

It will be apparent to those skilled in the art that various modifications to the preferred embodiments of the disclosure as described herein can be made without departing from the spirit or scope of the disclosure as defined in the appended claims. Thus, the disclosure covers the modifications and variations provided they come within the scope of the appended claims and the equivalents thereto.

What is claimed is:

1. A method of performing plasma-enhanced atomic-layer deposition with reduced quartz-based contamination, comprising:
forming an initial film on a substrate using a precursor gas;
purging the precursor gas;
inductively forming in a quartz plasma tube a hydrogen-based (H-based) plasma from a feed gas that consists essentially of either hydrogen and nitrogen or hydrogen, argon and nitrogen, wherein the nitrogen constitutes 2 vol % or less of the feed gas, wherein the H-based plasma includes one or more reactive species; and
directing the one or more reactive species to the substrate to cause the one or more reactive species to react with the initial film.

2. The method according to claim 1, wherein the substrate resides within an interior of a reactor chamber, the H-based plasma is formed in a plasma source pneumatically coupled to the interior of the reactor chamber, and wherein the act of directing the one or more reactive species to the substrate includes forming a pressure differential between the H-based plasma and the interior of the reactor chamber.

3. The method according to claim 1, further comprising forming the feed gas by combining the nitrogen and the hydrogen or the nitrogen, the hydrogen and the argon, wherein the nitrogen is added in the form of N₂ gas or NH₃ gas and wherein the hydrogen is added in the form of H₂ gas.

4. The method according to claim 1, wherein the nitrogen constitutes between 0.1 vol % and 2 vol % of the feed gas.

5. The method according to claim 4, wherein the nitrogen constitutes between 0.5 vol % and 1.5 vol % of the feed gas.

6. The method according to claim 1, wherein the nitrogen constitutes 1 vol % or less of the feed gas.

7. The method according to claim 1, wherein the precursor gas contains at least one of: niobium, tungsten, molybdenum, aluminum, gallium, indium, boron, copper, gadolinium, hafnium, silicon, tantalum, titanium, vanadium and zirconium.

8. The method according to claim 1, wherein the amount of the reduction of the quartz-based contamination is greater than 50× as compared to not using N in the feed gas.

9. The method according claim 1, wherein the amount of the reduction of the quartz-based contamination is greater than 20× as compared to not using nitrogen in the feed gas.

10. The method according to claim 1, wherein the amount of the reduction of the quartz-based contamination is greater than 2× as compared to not using nitrogen in the feed gas.

11. A method of forming a hydrogen-based (H-based) plasma for use in a plasma reactor system that includes a quartz plasma tube, comprising:
flowing a feed gas through the quartz plasma tube, wherein the feed gas consists of either H and N or H, Ar and N;
inductively forming from the feed gas flowing through the quartz plasma tube the H-based plasma; and
wherein the amount of N in the feed gas constitutes between 0.1 vol % and 2 vol % of the feed gas.

12. The method according to claim 11, wherein the N in the feed gas constitutes between 0.5 vol % and 1.5 vol % of the feed gas.

13. The method according to claim 11, wherein the N in the feed gas constitutes between 0.1 vol % and 1 vol % of the feed gas.

14. The method according to claim 11, wherein the H-based plasma includes at least one reactive specie, and further comprising using the at least one reactive specie in a plasma-enhanced atomic-layer deposition (PE-ALD) process to form a film on a substrate.

15. The method according to claim 14, wherein using the H-based plasma results in a reduction in an amount of quartz-based contamination of the film formed in the PE-ALD process that is greater than 50× as compared to not using N in the feed gas.

16. The method according to claim 14, wherein using the H-based plasma results in a reduction in an amount of quartz-based contamination of the film formed in the PE-ALD process that is greater than 20× as compared to not using N in the feed gas.

17. The method according to claim 14, wherein using the H-based plasma results in a reduction in an amount of quartz-based contamination of the film formed in the PE-ALD process that is greater than 2× as compared to not using N in the feed gas.

18. The method according to claim 14, wherein the PE-ALD process includes using a precursor gas having at least one of: niobium, tungsten, molybdenum, aluminum, gallium, indium, boron, copper, gadolinium, hafnium, silicon, tantalum, titanium, vanadium and zirconium.

19. The method according to claim 14, further comprising forming the feed gas by combining N and H or N, H and Ar, wherein the N is added in the form of N₂ gas or NH₃ gas and wherein the H is added in the form of H₂ gas.

20. The method according to claim 14, wherein the at least one reactive specie is H*, and further comprising causing the H* to react with an initial film to form the film on the substrate.

21. The method according to claim 14, wherein the feed gas consists essentially of either H and N or H, N and Ar.

22. The method according to claim 14, wherein the at least on reactive species includes H* and at least one of O*, C* and S*.
